(19) United States
(12) Patent Application Publication
(10) Pub. No.: US 2013/0089678 A1
(43) Pub. Date: Apr. 11, 2013

(54) PLASMA-ENHANCED DEPOSITION OF NICKEL-CONTAINING FILMS FOR VARIOUS APPLICATIONS USING AMIDINATE NICKEL PRECURSORS

(71) Applicants: Christian DUSSARRAT, Wilmington, DE (US); Vincent M. OMARJEE, Grenoble (FR); Clement LANSALOT-MATRAS, Tsukuba (JP)

(72) Inventors: Christian DUSSARRAT, Wilmington, DE (US); Vincent M. OMARJEE, Grenoble (FR); Clement LANSALOT-MATRAS, Tsukuba (JP)

(73) Assignee: American Air Liquide, Inc., Fremont, CA (US)

(21) Appl. No.: 13/269,115

(22) Filed: Oct. 7, 2011

(51) Int. Cl. C23C 16/18; C23C 16/50

(52) U.S. Cl. 427/576

(57) ABSTRACT

The disclosure relates to a process for depositing a Nickel or Cobalt containing film comprising the step of providing a metal guanidinate and/or metal amidinate precursor, suitable for plasma deposition at temperature equal or lower than 500 degrees C., to a plasma deposition process comprising a deposition temperature equal or lower than 500 degrees C.

### TECHNICAL FIELD

The present invention relates to a process for the use of metal amidinate metal precursors for the deposition of metal containing film via Plasma Enhanced Atomic Layer Deposition (PEALD) or Plasma Enhanced Chemical Vapor Deposition (PECVD).

### BACKGROUND ART

For contact applications, Nickel became the preferred metal. The final target is to obtain Nickel by (Plasma Enhanced)Atomic Layer Deposition (ALD) to form NiSi contacts to source, drain and gate in CMOS devices. ALD is the preferred method because it allows a high film quality, a high film uniformity and conformality even on highly irregular or exotic structures. Cobalt containing metal, silicide or oxide is also of interest for various applications such as metal electrode, barrier layer in BEOL. Nickel silicide will replace Cobalt silicide (CoSi₂, which had replaced TiSi₂) for the current generation dimensional node, typically under 60 nm. Some factors necessitating the replacement of CoSi₂ are that CoSi₂ is not compatible with Ge-containing substrate and requires a high temperature formation process.

The use of Nickel presents many advantages. First of all, the silicide formation can be done at low temperature (less than 600° C., to avoid the undesired NiSi₂ phase). The sheet resistance is also very low, typically between 15 and 20 μΩcm and insensitive to line width. These advantages also make Nickel silicide superior to the predicate materials of CoSi₂ or TiSi₂. The Nickel diffusion in Silicon is easy to control. Last but not least, NiSi films can be stabilized by using Pd, Pt and Fluorine (coming from BF₂ for instance). Such incorporation will shift the NiSi₂ formation to higher temperature making NiSi the dominant phase within a wider process temperature range.

Ni(tBuAMD)2 has been described in U.S. Pat. No. 7,964,490B2 and at ALD 2010 (Intel: Clendenning et al.). The use of this precursor is for the distinct application of forming Nickel sulfide films.

Kim et al. (ADMETA 2009 conference) showed the use of Co(CpAMD) in PEALD using NH3 as co-reactant. Films with higher resistivity than CoCp2 were obtained.

Lee et al. (Electrochemical and Solid-State Letters, 9, 11, G323-G325, 2006) used CoCp2 and CoCp(CO)2 to deposit Co by PEALD using NH3 plasma. Films deposited with PEALD NH3 were found to be better compared to thermal ALD with a H2 co-reactant. However, CoCp(CO)2 was found not to be suitable for ALD (no self-saturation). CoCp2 led to an ALD regime; however, CoCp2 is a solid with low vapor pressure. These physical properties make CoCp2 impractical as a material for commercial use.

Lee et al. (Journal of the Korean Physical Society, Vol. 56, No. 1, January 2010, pp. 104-107) used Co(iPr-AMD)2 with NH3 in thermal or plasma ALD. The desired results for Plasma-enhanced ALD were not achieved because there was no selective deposition under the conditions tested.

Chae et al. (Electrochemical and Solid-State Letters, 5, 6 C64-C66 2002) deposited NiO2 that was followed by hydrogen radical reduction using Ni(Cp)2 ALD with H2O. These 2 steps processes generally yield very thin film discontinuity. More critical to Nickel silicide formation, the reduction step isn't complete leaving oxygen into the film. For a silicidation target, residual oxygen would prevent mixing of silicon and nickel thus inhibiting Nickel silicide formation.

Lee et al. (Japanese Journal of Applied Physics 49 (2010)) used bis(dimethylamino-2-methyl-2-butoxo)nickel [Ni(dmamb)2] as a precursor and NH3 or H2 plasma as a reactant. While no O was detected, some N and C were retained in the films. Ni(dmamb)2 is also a solid at room temperature, making it a suboptimal precursor for vapor deposition processes.

Additional deposition work with metal amidinate precursors is described in U.S. 2010/0092667 A1.

### DISCLOSURE OF INVENTION

The invention may be defined in part by reference to the following paragraphs [00012]-[00024]:
A process for depositing a Nickel or Cobalt containing film comprising the step of providing a metal guanidinate and/or metal amidinate precursor, suitable for plasma deposition at temperature equal or lower than 500 degrees C., to a plasma deposition process comprising a deposition temperature equal or lower than 500 degrees C.
The method of paragraph [00012], wherein the deposition temperature is at a temperature of 20-500 degrees C.
The method of paragraph [00012], wherein the deposition temperature is at a temperature of 50-300 degrees C.
The method of paragraph [00012], wherein the deposition temperature is at a temperature of 100-300 degrees C.
The method of paragraph [00012], wherein the deposition temperature is at a temperature of 200-300 degrees C.
The method of any one of paragraphs [00012]-[00016], wherein the metal containing film is deposited on a substrate coated with one or more of Ru, Ta, TaN, SiO₂.
The method of any one of paragraphs [00012]-[00016] or the combination of any one of paragraphs [00012]-[00016] with paragraph [00017], further comprising a step of providing at least one co-reactant amine or reducing agent to the plasma deposition process.
The method of any one of paragraphs [00012]-[00016] or the combination of any one of paragraphs [00012]-[00016] with one or both of paragraphs [00017] and [00018], further comprising a step of providing to the plasma deposition process at least one co-reactant oxygen source selected from O₂, O₃, H₂O, H₂O₂, NO, NO₂, or a carboxylic acid.
The method of any one of paragraphs [00012]-[00016] or the combination of any one of paragraphs [00012]-[00016] with any one of or any combination of paragraphs [00017]-[00019], wherein the plasma deposition process is a PECVD process.
The method of paragraph [00018] wherein the plasma deposition process is a PEALD process comprising a plurality of cycle.
The method of any one of paragraphs [00012]-[00016] or the combination of any one of paragraphs [00012]-[00016] with any one of or any combination of paragraphs [00017]-[00021], wherein the metal film is substantially pure metal.
The method of any one of paragraphs [00012]-[00016] or the combination of any one of paragraphs [00012]-[00016] with any one of or any combination of paragraphs [00017]-[00022], wherein the film is a Nickel-containing film and the suitable metal precursor has the structure of compound (II) wherein M is Ni; and R₁ and R₃ are independently selected from H, a C1-C5 alkyl group, and Si(R′)₃, where R′ is independently selected from H, and a C1-C5 alkyl group. R₂ is independently selected from H, a C1-C5 alkyl group, and NR′R″, where R′ and R″ are independently selected from C1-C5 alkyl groups.

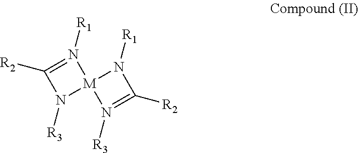

The method of any one of paragraphs [00012]-[00016] or the combination of any one of paragraphs [00012]-[00016] with any one of or any combination of paragraphs [00017]-[00022], where the preferred metal precursor is bis(N,N′-diisopropylpentylamidinato) Nickel (II).

The present invention relates to a process for the use of Cobalt and Nickel metal amidinate precursors for the deposition of metal containing films via Plasma Enhanced Atomic Layer Deposition (PEALD) or Plasma Enhanced Chemical Vapor Deposition (PECVD). Plasma improves deposition rates and/or film properties, especially at low deposition temperatures. The preferred metal of the invention is Nickel.

In some embodiments, the present invention provides methods of depositing pure metal Cobalt or Nickel film by plasma enhanced atomic layer deposition (PEALD) and plasma enhanced chemical vapor deposition (PECVD). “Pure metal” is defined as at least 90% metal such as 95% or more metal, 99% or more metal or 99.9% or more metal.

In some embodiments of the invention, metal amidinate or metal guanidinate is used at low deposition temperatures.

In some embodiments, the metal deposition method includes the steps of providing a substrate; providing a vapor of a metal guanidinate or a metal amidinate precursor; and contacting the vapor including the at least one Copper precursor with the substrate (and typically directing the vapor to the substrate) to form a metal containing layer on at least one surface of the substrate at temperature of 400 degrees C. or lower, preferably between 50 and 300 degrees C.

In one embodiment of the invention, the metal precursor is represented by compound (II)

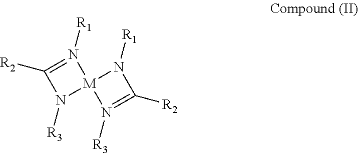

wherein:

M is Co or Ni; preferably Ni; and

R₁ and R₃ are independently selected from H, a C1-c5 alkyl group, and Si(R′)₃, where R′ is independently selected from H, and a C1-C5 alkyl group. R₂ is independently selected from H, a C1-C5 alkyl group, and NR′R″, where R′ and R″ are independently selected from C1-C5 alkyl groups. An exemplary species of the metal precursor is bis(N,N′-diisopropylpentylamidinato) Nickel(II).

Deposition conditions for the invention include temperatures in the range of 20-500 degrees C., preferably below 300 degrees C. such as 50-300 degrees C., 100-250 degrees C., or 200-250 degrees C. Deposition conditions for the invention may also include pressures ranging from 0.5 mTorr to 20 Torr to deposit films having the general formula M, MₖSiₗ, MₙOₘ or MₓN_{y}O_{z}. Film composition will be dependent on the application. Where k, l, m, n, x, y range from 1 to 6, inclusive. The deposition may include one or more co-reactants such as an amine containing reactant or a reducing agent. Exemplary co-reactants are H₂, NH₃, diethylsilane, BuNH₂, B₂H₆, GeH₄, SnH₄, AlH₃, or an alkyl silane containing a Si—H bond. The deposition may include one or more co-reactant oxygen sources preferably O₂, O₃, H₂O, H₂O₂, NO, NO₂, a carboxylic acid, dimethylsilane. The metal precursor may be delivered in neat form or in a blend with a suitable solvent, preferably Ethyl benzene, Xylenes, Mesitylene, Decane, or Dodecane in suitable concentrations.

In some but non-limiting embodiments, preferred applications could be

Metal deposition on silicon to ultimately form metal silicide, metal deposition on Ta, TaN or WN to ultimately form metal layer, and metal oxide deposition for ReRAM applications.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

What is claimed is:

1. A process for depositing a Nickel or Cobalt containing film comprising the step of providing a metal guanidinate and/or metal amidinate precursor, suitable for plasma deposition at temperature equal or lower than 500 degrees C., to a plasma deposition process comprising a deposition temperature equal or lower than 500 degrees C.

2. The method of claim 1, wherein the deposition temperature is at a temperature of 20-500 degrees C.

3. The method of claim 1, wherein the deposition temperature is at a temperature of 50-300 degrees C.

4. The method of claim 1, wherein the deposition temperature is at a temperature of 100-300 degrees C.

5. The method of claim 1, wherein the deposition temperature is at a temperature of 200-300 degrees C.

6. The method of claim 1, wherein the metal containing film is deposited on a substrate coated with one or more of Ru, Ta, TaN, SiO₂.

7. The method of claim 1, further comprising a step of providing at least one co-reactant amine or reducing agent to the plasma deposition process.

8. The method of claim 1, further comprising a step of providing to the plasma deposition process at least one co-reactant oxygen source selected from O₂, O₃, H₂O, H₂O₂, NO, NO₂, or a carboxylic acid.

9. The method of claim 1, wherein the plasma deposition process is a PECVD process.

10. The method of claim 7, wherein the plasma deposition process is a PEALD process comprising a plurality of cycle.

11. The method of claim 1, wherein the metal film is substantially pure metal.

12. The method of claim 1, wherein the film is a Nickel-containing film and the suitable metal precursor has the structure of compound (II) 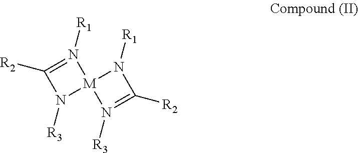
wherein M is Ni; and R₁ and R₃ are independently selected from H, a C1-C5 alkyl group, and Si(R′)₃, where R′ is independently selected from H, and a C1-C5 alkyl group. R₂ is independently selected from H, a C1-C5 alkyl group, and NR′R″, where R′ and R″ are independently selected from C1-C5 alkyl groups.

13. The method of claim 12, where the preferred metal precursor is bis(N,N′-diisopropylpentylamidinato) Nickel (II).
